(19) United States
(12) Patent Application Publication
(10) Pub. No.: US 2024/0304766 A1
(43) Pub. Date: Sep. 12, 2024

(54) LIGHT-EMITTING DEVICE PACKAGE AND LIGHTING DEVICE INCLUDING THE SAME

(71) Applicant: Samsung Electronics Co., Ltd., Suwon-si (KR)

(72) Inventors: Hanhyoung Kim, Suwon-si (KR); Jaesung You, Suwon-si (KR); Hyeongdu Choi, Suwon-si (KR)

(21) Appl. No.: 18/417,508

(22) Filed: Jan. 19, 2024

(30) Foreign Application Priority Data
Mar. 7, 2023 (KR) 10-2023-0030200

(51) Int. Cl. H01L 33/54; H01L 33/62

(52) U.S. Cl. CPC H01L 33/54; H01L 33/62

(57) ABSTRACT

A light-emitting device package includes a mold, a first electrode and a second electrode that are at least partially buried in the mold, a first light source disposed on the first electrode and electrically connected thereto, and a coating layer disposed on a first portion of the first electrode and a second portion of the second electrode. A thickness of the coating layer is 40 nm or more.

### CROSS-REFERENCE TO RELATED APPLICATION

This application is based on and claims priority under 35 U.S.C. §119 to Korean Patent Application No. 10-2023-0030200, filed on Mar. 7, 2023, in the Korean Intellectual Property Office, the disclosure of which is incorporated by reference herein in its entirety.

### BACKGROUND

The inventive concept relates to a light-emitting device package and a lighting device including the same. More particularly, the inventive concept relates to a light-emitting device package having improved reliability and performance by using a multi-layered coating layer, and a lighting device including the same.

As a representative example of a light-emitting device, a light-emitting diode (LED) is a device that converts an electrical signal into infrared light, visible light, or the like by using characteristics of a compound semiconductor. LEDs are used in household appliances, remote controllers, electronic display boards, indicators, various automation devices, or the like, and the use of LEDs has expanded.

Miniaturized LEDs are made in a form of a surface mount device in order to be directly mounted on a printed circuit board (PCB) substrate. Accordingly, LED lamps used as display devices are also developed in a form of a surface mount device. Surface mount devices may replace existing simple lighting lamps and may be used as lighting indicators, text indicators, and image indicators that emit various colors.

As the use of LED has expanded, LEDs are mainly used as lighting devices in a stable indoor environment but are requested to be used as high-reliability lighting devices, such as garden lights, security lights, or street lights, even in an outdoor environment that changes variously. In order to meet such requirements, LED package devices with LED chips bonded to high-cost, high-reliability ceramic substrates have begun to be used.

Light source devices with LED chips bonded to lead frames are mainly used in indoor living areas and have high cost effectiveness. However, when silver (Ag) is used as a reflection layer of a lead frame, outdoor environmental factors (smoke, high/low temperature, salt, etc.) may easily cause oxidation and discoloration of the reflection layer. Accordingly, relative reliability of light source devices is lowered, making it difficult to employ light source devices in outdoor environments.

### SUMMARY

The inventive concept provides a light-emitting device package, in which reliability and performance are improved by forming a multi-layered coating layer, and a lighting device including the same.

The technical objectives of the inventive concept are not limited to the above object, and other objects that are not mentioned herein will be clearly understood by those of ordinary skill in the art from the following description.

To achieve the technical objectives of the inventive concept, the inventive concept provides light-emitting device packages as follows.

According to an embodiment of the present disclosure, a light-emitting device package includes a mold, a first electrode and a second electrode that are at least partially buried in the mold, a first light source disposed on the first electrode and electrically connected thereto, and a coating layer disposed on a first portion of the first electrode and a second portion of the second electrode. A thickness of the coating layer is 40 nm or more.

According to an embodiment of the present disclosure, a light-emitting device package includes a mold provided with a recess, a first electrode and a second electrode that are at least partially buried in the mold, a first light source disposed in the recess and electrically connected to the first electrode, a silver (Ag) wire connecting the first light source to the second electrode, and a coating layer disposed on a first portion of the first electrode, a second portion of the second electrode, an outer surface of the Ag wire, and an inner surface of the recess. A thickness of the coating layer is 80 nm or less.

To achieve the technical objectives of the inventive concept, the inventive concept provides a lighting device as follows.

According to an embodiment of the present disclosure, a lighting device includes a light-emitting device package. The light-emitting device package includes a mold provided with a plurality of electrodes and a recess partially exposing a first electrode and a second electrode among the plurality of electrodes, a light source electrically connected to the first electrode, a coating layer disposed on a first portion of the first electrode and a second portion of the second electrode. A thickness of the coating layer is selected from a range of 40 nm to 80 nm.

### BRIEF DESCRIPTION OF THE DRAWINGS

Embodiments will be more clearly understood from the following detailed description taken in conjunction with the accompanying drawings in which:

FIG. 1 is a perspective view illustrating a light-emitting device package according to an embodiment;

FIG. 2 is a cross-sectional view of the light-emitting device package of FIG. 1 taken along line A-B of FIG. 1;

FIG. 3A is a cross-sectional view illustrating a light-emitting device package according to another embodiment;

FIG. 3B is an enlarged cross-sectional view of region CC of FIG. 3A;

FIG. 4 is a cross-sectional view illustrating a light-emitting device package according to another embodiment;

FIG. 5A is a cross-sectional view illustrating a light-emitting device package according to another embodiment;

FIG. 5B is an enlarged cross-sectional view of region DD of FIG. 5A;

FIG. 6 is a perspective view illustrating a lighting device including a light-emitting device package, according to an embodiment;

FIG. 7 is a cross-sectional view of the lighting device of FIG. 6 taken along line E-E′ of FIG. 6;

FIG. 8 is an exploded perspective view of a liquid crystal display including a light-emitting device package, according to an embodiment; and

FIG. 9 is an exploded perspective view of a liquid crystal display including a light-emitting device package, according to an embodiment.

### DETAILED DESCRIPTION OF THE EMBODIMENTS

Hereinafter, preferred embodiments will be described in detail with reference to the accompanying drawings. The same elements in the drawings are denoted by the same reference numerals, and redundant descriptions thereof are omitted.

The present embodiments allow for various changes and numerous embodiments, and specific embodiments will be illustrated in the drawings and described in detail in the following detailed description. However, this is not intended to limit the inventive concept to a specific form disclosed herein, and it should be understood that the inventive concept includes all changes, equivalents, and substitutes falling within the spirit and scope of the inventive concept. In describing embodiments, when the detailed description of the relevant known functions or configurations is determined to unnecessarily obscure the gist of the inventive concept, the detailed description thereof may be omitted herein.

While the terms as “first” and “second” may be used to describe various elements, such elements should not be limited by these terms. These terms are only used to distinguish one element from another. For example, while not departing from the scope of the inventive concept, a first element may be referred to as a second element, and similarly, a second element may be referred to as a first element.

In the drawings, the thicknesses or sizes of layers are exaggerated, omitted, or schematically illustrated for convenience and clarity of explanation. Also, the sizes and areas of elements do not entirely reflect the actual sizes and areas.

The angles and directions described in the process of explaining a structure of a light-emitting device in an embodiment are based on those described in the drawings. In the description of the structure constituting the light-emitting device in the specification, when reference points and positional relationships for angles are not clearly described, reference is made to related drawings.

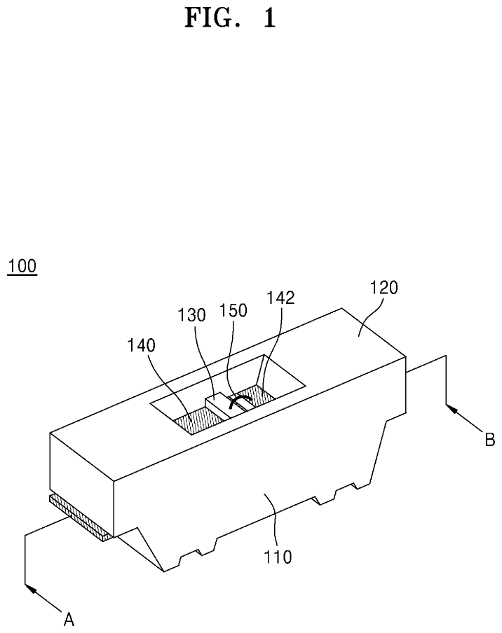

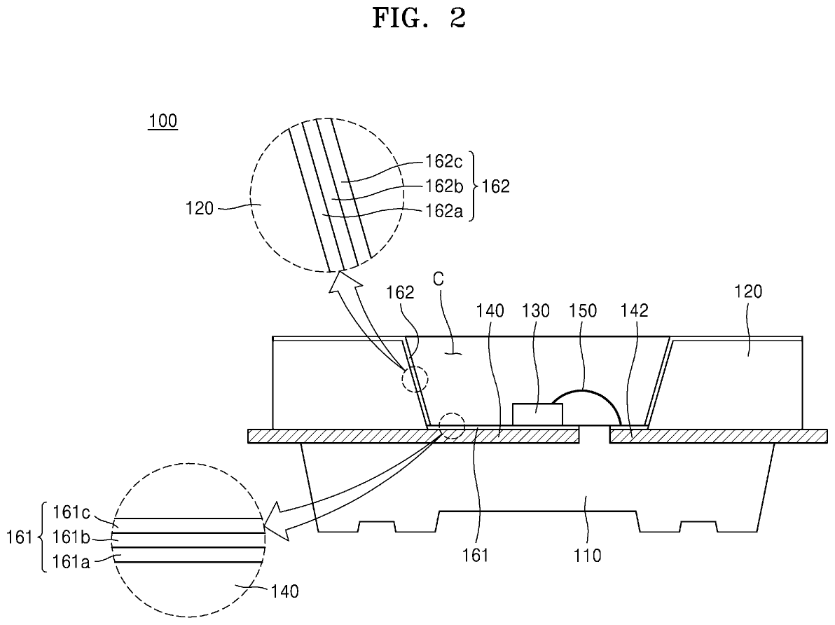

FIG. 1 is a perspective view illustrating a light-emitting device package 100 according to an embodiment, and FIG. 2 is a cross-sectional view of the light-emitting device package 100 of FIG. 1 taken along line A-B of FIG. 1.

Referring to FIGS. 1 and 2, the light-emitting device package 100 according to an embodiment may include a mold 110 including a cavity C (i.e., an opening or a recess) and a sidewall 120 (i.e., a sidewall portion), a first electrode 140 and a second electrode 142 mounted on the mold 110, a light source 130 electrically connected to the first electrode 140 and the second electrode 142, and a first coating layer 161 disposed on the first electrode 140 and the second electrode 142. In some embodiments, the light source 130 may contact the first electrode 140. For example, the first coating layer 161 may not be disposed between a bottom surface of the light source 130 and an upper surface of the first electrode 140. In some embodiments, the first coating layer 161 may contact each of the first and second electrodes 140 and 142. In some embodiments, an upper surface of the mold 110 may be recessed toward the first and second electrodes 140 and 142 to form a recess which at least partially exposes the first and second electrodes 140 and 142. The recess may be referred to as the cavity C or an opening. In some embodiments, the first and second electrodes 140 and 142 may be partially buried in the mold 110. In some embodiments, the sidewall portion 120 of the mold 110 may be disposed on an upper surface of each of the first and second electrodes 140 and 142, and the cavity C of the mold 110 may partially expose the first and second electrodes 140 and 142. The term “contact,” as used herein, refers to a direct connection (i.e., physical touching) unless the context indicates otherwise.

The mold 110 may include or may be formed of at least one selected from a resin material such as polyphthalamide (PPA), silicon (Si), aluminum (Al), aluminum nitride (AlN), liquid crystal polymer (photo sensitive glass (PSG)), polyamide 9T (PA9T), syndiotactic polystyrene (SPS), a metal material, sapphire (Al₂O₃), beryllium oxide (BeO), and a printed circuit board (PCB). The mold 110 may be formed by injection molding, etching, or the like, but the inventive concept is not limited thereto.

As the cavity C is formed in the mold 110, the sidewall 120 surrounding the cavity C is formed. The inner surface of the sidewall 120 may include an inclined surface. A reflection angle of light emitted from the light source 130 may vary depending on the angle of the inclined surface. For example, the angle of the inclined surface may determine the beam spread angle of light emitted to the outside. FIG. 1 illustrates only a case where the cavity C is present, but the inventive concept may also be applied to a chip-on-board (COB) type without the cavity C. However, the inventive concept is not limited thereto.

As the beam spread angle decreases, the concentration of light emitted from the light source 130 to the outside increases. In contrast, as the beam spread angle increases, the concentration of light emitted from the light source 130 to the outside decreases.

When viewed from above, the cavity C formed in the mold 110 may have a circular shape, a rectangular shape, a polygonal shape, an elliptical shape, or the like, or may have a shape with curved corners, but the inventive concept is not limited thereto.

Although FIG. 1 illustrates a trim type light-emitting device package in which a portion of an electrode protrudes out of the mold 110, this is only an example and the technical idea of the inventive concept is not limited thereto. For example, the technical idea of the inventive concept may be applied even when the electrode does not protrude out of the mold 110 by using a sawing type when separating the light-emitting device package.

The light source 130 may be electrically connected to the first and second electrodes 140 and 142. For example, as illustrated in FIG. 2, the light source 130 may be mounted on the first electrode 140, and the light source 130 may be wire-bonded to the second electrode 142 by a wire 150. For example, the wire 150 may contact the second electrode 142. The light source 130 may be wire-bonded to the first electrode 140 and the second electrode 142 by the wire 150. However, the inventive concept is not limited thereto.

The light source 130 may be, for example, a light-emitting diode. The light-emitting diode may be, for example, a color light-emitting diode that emits red light, green light, blue light, or white light, or an ultraviolet (UV) light-emitting diode that emits ultraviolet light, but the inventive concept is not limited thereto. One or more light-emitting diodes may be provided in the light source 130. When two or more light-emitting diodes are provided in the light source 130, the two or more light-emitting diodes are connected to the first and second electrodes 140 and 142 in parallel.

The light-emitting diode may be applied to a horizontal type light-emitting diode having electrical terminals formed on an upper surface thereof, a vertical type light-emitting diode having electrical terminals formed on upper and lower surfaces thereof, or a flip chip.

Each of the first electrode 140 and the second electrode 142 may include or may be formed of copper (Cu). The present invention is not limited thereto. In some embodiments, each of the first electrode 140 and the second electrode 142 may include or may be formed of metal other than Cu. For example, each of the first electrode 140 and the second electrode 142 may include or may be formed of at least one of titanium (Ti), nickel (Ni), gold (Au), chromium (Cr), tantalum (Ta), platinum (Pt), tin (Sn), silver (Ag), phosphorus (P), aluminum (Al), indium (In), palladium (Pd), cobalt (Co), silicon (Si), germanium (Ge), hafnium (Hf), ruthenium (Ru), iron (Fe), and an alloy thereof. The first and second electrodes 140 and 142 may each be formed to have a single-layered or multi-layered structure. As illustrated, the two electrodes, that is, the first and second electrodes 140 and 142, or several electrodes (not shown) may be provided in the light source 130, but the inventive concept is not limited thereto. The number of electrodes and the number of light-emitting devices are not limited to the drawings of the present specification, and a plurality of light-emitting devices may be mounted in one light-emitting device package. The first and second electrodes 140 and 142 may each be plated with Ag. For example, Ag may be plated at an upper surface of each of the first and second electrodes 140 and 142.

The wire 150 may be an Ag wire. Although one wire 150 is illustrated in the drawing of the present specification, the number of wires 150 is not limited thereto.

One or more electrically conductive wires 150 may electrically connect the light source 130 to the first and second electrodes 140 and 142 by welding, soldering, or any other bonding methods. An electrical current or signal may electrically pass through the wire 150.

When a portion of the light-emitting device package includes Ag, there is a possibility that Ag may be discolored, corroded, or deteriorated in other ways when the light-emitting device package does not have good chemical resistance. For example, when the light-emitting device package is infiltrated with unwanted chemicals, Ag may blacken or deteriorate, leading to discoloration of the light-emitting device package and loss of luminous flux output.

Many chemical vapors or gases may cause blackening or discoloration of Ag or Ag-containing components in the light-emitting device package. For example, sulfur and many sulfur-containing compounds may cause blackening of Ag upon contact with Ag. The sulfur compounds include sulfides, sulfites, and sulfates. Examples of the sulfur-containing compounds include hydrogen sulfide (H₂S), sulfur compounds, sulfur dioxide (SO₂), or carbon disulfide (CS₂). Other sulfur-containing compounds may be found in vulcanized rubber and may be a source of sulfur compounds that cause Ag degradation. Examples of such compounds may include sodium metabisulfite, mercaptan, dimethyldithiocarbamate, or aluminum sulfate, but the inventive concept is not limited thereto.

Therefore, it is necessary to prevent deterioration of the light-emitting device package by providing chemical resistance through a coating process using an appropriate coating layer or the like on a region including Ag.

A first coating layer 161 may be on the first electrode 140 and/or the second electrode 142. The first coating layer 161 may be in all areas on the first electrode 140 and/or the second electrode 142 or in an area exposed to the inside of the cavity C as illustrated in FIG. 2, but the inventive concept is not limited thereto. The first coating layer 161 may include or may be formed of Al₂O₃, TiO₂, SiO₂, CrO, Ti, or the like, but the inventive concept is not limited thereto. The first coating layer 161 may reflect light directed toward the first and second electrodes 140 and 142 in the upper direction of the light-emitting device package 100. Accordingly, the reflectance using the interference phenomenon may be increased, and thus, the performance may be further improved.

The first coating layer 161 may include three or more layers including first to third layers 161a, 161b, and 161c. The thickness of the first coating layer 161 may be 40 nm or more, and it may be determined that a significant performance improvement occurs at such a thickness. The “thickness” of the coating layer described herein may refer to the thickness of the coating layer formed at the widest flat portion inside the light-emitting device package. The first coating layer 161 may be coated in three or more layers to improve reliability. In this case, reliability may refer to lifespan, sulfur resistance, flame resistance, or moisture resistance. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

In the first coating layer 161, an Al₂O₃ layer may be formed on the first layer 161a to a thickness of about 20 nm, a TiO₂ layer may be formed on the second layer 161b to a thickness of about 20 nm, and a SiO₂ layer may be formed on the third layer 161c to a thickness of about 20 nm. In some embodiments, the first coating layer 161 may include or may be formed of an Al₂O₃ having a thickness of about 20 nm as the first layer 161a, a TiO₂ layer having a thickness of about 20 nm as the second layer 161b, and a SiO₂ layer having a thickness of about 20 nm as the third layer 161c. The first coating layer 161 formed as described above may exhibit a reflectance of about 95% at a specific wavelength. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In the first coating layer 161, an Al₂O₃ layer may be formed on the first layer 161a to a thickness of about 15 nm, a TiO₂ layer may be formed on the second layer 161b to a thickness of about 30 nm, and a SiO₂ layer may be formed on the third layer 161c to a thickness of about 10 nm. In some embodiments, the first coating layer 161 may include or may be formed of an Al₂O₃ having a thickness of about 15 nm as the first layer 161a, a TiO₂ layer having a thickness of about 30 nm as the second layer 161b, and a SiO₂ layer having a thickness of about 10 nm as the third layer 161c.

In the first coating layer 161, an Al₂O₃ layer may be formed on the first layer 161a to a thickness of about 20 nm, a SiO₂ layer may be formed on the second layer 161b to a thickness of about 10 nm, and a TiO₂ layer may be formed on the third layer 161c to a thickness of about 30 nm. In some embodiments, the first coating layer 161 may include or may be formed of an Al₂O₃ having a thickness of about 20 nm as the first layer 161a, a TiO₂ layer having a thickness of about 10 nm as the second layer 161b, and a SiO₂ layer having a thickness of about 30 nm as the third layer 161c. The first coating layer 161 formed as described above may exhibit a reflectance of about 98% at a specific wavelength. However, the technical idea of the inventive concept is not limited thereto.

A second coating layer 162 may be formed on the inner surface of the cavity C. The second coating layer 162 that is formed on the inner surface of the sidewall 120 may increase the luminous intensity and light efficiency. In some embodiments, the second coating layer 162 may contact the inner surface of the sidewall 120.

The second coating layer 162 may include or may be formed of Al₂O₃, TiO₂, SiO₂, CrO, Ti, or the like, but the inventive concept is not limited thereto. The second coating layer 162 may be integrally formed with the first coating layer 161 to prevent infiltration of external materials.

The second coating layer 162 may include three or more coating layers. In some embodiment, the second coating layer 162 may include or may be formed of first, second, and third layers 162a, 162b, and 162c. The thickness of the second coating layer 162 may be 40 nm or more. The second coating layer 162 may be coated in three or more layers to improve reliability.

In the second coating layer 162, an Al₂O₃ layer may be formed on the first layer 162a to a thickness of about 20 nm, a TiO₂ layer may be formed on the second layer 162b to a thickness of about 20 nm, and a SiO₂ layer may be formed on the third layer 162c to a thickness of about 20 nm.

In the second coating layer 162, an Al₂O₃ layer may be formed on the first layer 162a to a thickness of about 15 nm, a TiO₂ layer may be formed on the second layer 162b to a thickness of about 30 nm, and a SiO₂ layer may be formed on the third layer 162c to a thickness of about 10 nm.

In the second coating layer 162, an Al₂O₃ layer may be formed on the first layer 162a to a thickness of about 20 nm, a SiO₂ layer may be formed on the second layer 162b to a thickness of about 10 nm, and a TiO₂ layer may be formed on the third layer 162c to a thickness of about 30 nm. The second coating layer 162 formed as described above may exhibit a reflectance of about 98% at a specific wavelength. However, the technical idea of the inventive concept is not limited thereto.

The second coating layer 162 may extend to the upper surface of the mold 110 as well as the inner surface of the sidewall 120. That is, the second coating layer 162 may be formed to cover the entire upper surface of the mold 110 when viewed from outside.

The first coating layer 161 and the second coating layer 162 may be inorganic layers and may be formed by repeatedly depositing a high refractive index material and a low refractive index material. The deposition of the first coating layer 161 and the second coating layer 162 may be performed by chemical vapor deposition (CVD), evaporation, sputtering, plasma enhanced chemical vapor deposition (PECVD), or the like.

As described above, because the light-emitting device package 100 includes the first coating layer 161 and the second coating layer 162, the light-emitting device package 100 may have an effect of reflecting light directed toward the first and second electrodes 140 and 142 among pieces of light generated by the light source 130 in the upper direction of the light-emitting device package 100, and may prevent oxidation of the first and second electrodes 140 and 142 and discoloration thereof.

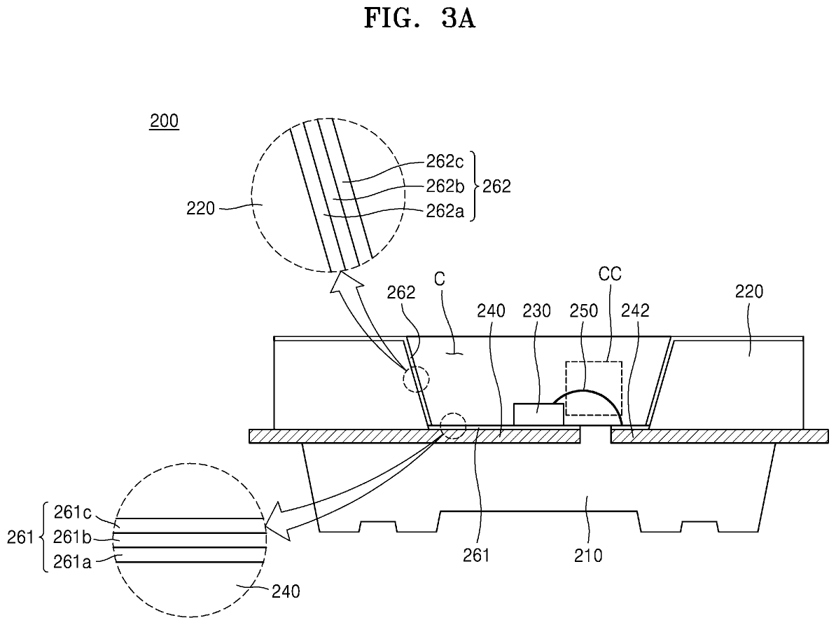

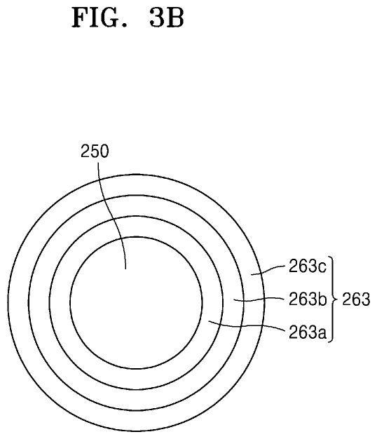

FIG. 3A is a cross-sectional view illustrating a light-emitting device package 200 according to another embodiment.

Hereinafter, descriptions redundant to those of FIG. 2 are omitted, and differences from FIG. 2 are mainly described.

Referring to FIG. 3A, in the light-emitting device package 200 according to another embodiment, a coating layer may also be formed on a wire 250, compared to the embodiment of FIG. 2. In the light-emitting device package 100 of FIG. 2, reliability and reflectance are enhanced by forming the coating layer before the light source 130 is bonded. In the light-emitting device package 200 of FIG. 3A, reliability and reflectance may be enhanced by coating the wire 150 and the first and second electrodes 240 and 242 after wire bonding of the wire 250 is performed.

FIG. 3B is an enlarged cross-sectional view of region CC of FIG. 3A. A third coating layer 263 may be formed on the wire 250.

Referring to FIGS. 3A and 3B, a first coating layer 261 may include three or more coating layers. In some embodiments, the first coating layer 261 may include or may be formed of first to third layers 261a, 261b, and 261c. A second coating layer 262 may include three or more coating layers. In some embodiments, the second coating layer 262 may include or may be formed of first to third layers 262a, 262b, and 262c. A third coating layer 263 may include three or more coating layers. In some embodiments, the third coating layer 263 may include or may be formed of first to third layers 263a, 263b, and 263c. In some embodiments, each of the first to third coating layers 261 to 263 may include or may be formed of the same layers as the other coating layers. The first to third coating layers 261, 262, and 263 may each have a thickness of 80 nm or less. In some embodiments, each of the first to third coating layers 261, 262, and 263 may have a thickness selected from a range of 40 nm to 80 nm. When the thickness of each of the first to third coating layers 261, 262, and 263 is greater than 80 nm, a contact defect may occur between the Ag surface and the electrode in a wire bonding area. The first to third coating layers 261, 262, and 263 may each be coated in three or more layers to improve reliability.

In the first to third coating layers 261, 262, and 263, an Al₂O₃ layer may be formed on the first layers 261a, 262a, and 263a to a thickness of about 20 nm, a TiO₂ layer may be formed on the second layers 261b, 262b, and 263b to a thickness of about 20 nm, and a SiO₂ layer may be formed on the third layers 261c, 262c, and 263c to a thickness of about 20 nm. The first to third coating layers 261, 262, and 263 formed as described above may exhibit a reflectance of about 94% at a specific wavelength.

In the first to third coating layers 261, 262, and 263, an Al₂O₃ layer may be formed on the first layers 261a, 262a, and 263a to a thickness of about 15 nm, a TiO₂ layer may be formed on the second layers 261b, 262b, and 263b to a thickness of about 30 nm, and a SiO₂ layer may be formed on the third layers 261c, 262c, and 263c to a thickness of about 10 nm. The first to third coating layers 261, 262, and 263 formed as described above may exhibit a reflectance of about 97% at a specific wavelength.

In the first to third coating layers 261, 262, and 263, an Al₂O₃ layer may be formed on the first layers 261a, 262a, and 263a to a thickness of about 20 nm, a SiO₂ layer may be formed on the second layers 261b, 262b, and 263b to a thickness of about 10 nm, and a TiO₂ layer may be formed on the third layers 261c, 262c, and 263c to a thickness of about 30 nm. The first to third coating layers 261, 262, and 263 formed as described above may exhibit a reflectance of about 98% at a specific wavelength. However, the technical idea of the inventive concept is not limited thereto.

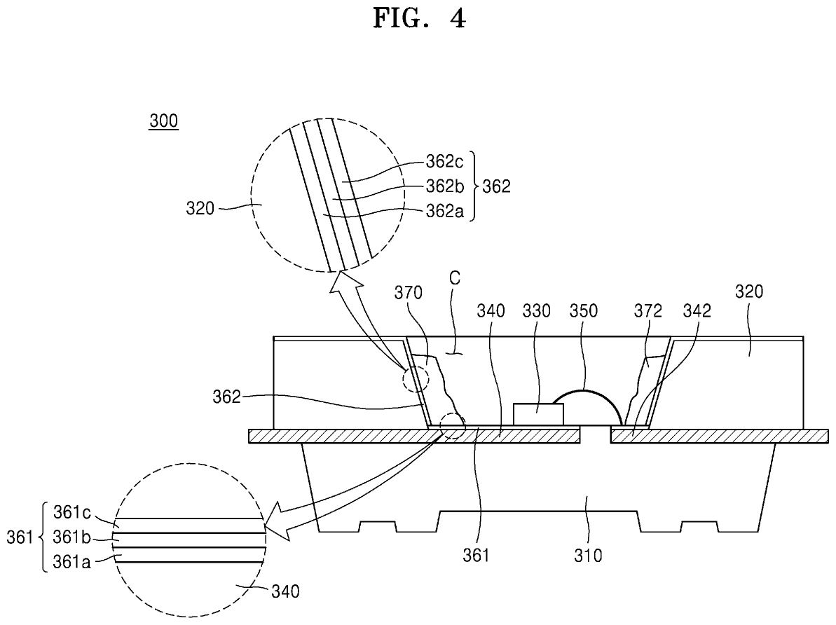

FIG. 4 is a cross-sectional view illustrating a light-emitting device package 300 according to another embodiment.

Similarly, hereinafter, descriptions redundant to those of FIGS. 2 and 3A are omitted, and differences from FIGS. 2 and 3A are mainly described.

Referring to FIG. 4, the light-emitting device package 300 may further include silicon layers 370 and 372. The silicon layers 370 and 372 may be formed to cover a portion of an inner surface of a cavity C.

A function of coating an upper surface of a mold 310 may be performed by forming the silicon layers 370 and 372. Therefore, discoloration of the mold 310 may be prevented. The silicon layers 370 and 372 may be formed to cover a portion of a sidewall 320, but the shapes and areas of the silicon layers 370 and 372 are not limited to the drawing of the present specification.

The internal structure of the light-emitting device package is not flat, and has a complicated configuration due to chips mounted in a small space of the light-emitting device package. In some embodiments, the silicon layer 370 may cover an inner surface of a lower portion of the sidewall 320 and a portion of the first electrode 340. The portion of the first electrode 340 may be connected to the lower portion of the sidewall 320. When first and second coating layers 361 and 362 are deposited using a physical deposition such as sputtering and evaporation, a corner portion where the inner surface of the lower portion of the sidewall 320 and the portion of the first electrode 340 may have a smaller thickness compared to when the second coating layer 362 is deposited on an inner surface of an upper portion of the sidewall 320 and an upper surface of the sidewall 320 or compared to when the first coating layer 361 is deposited a center region of a bottom surface of the cavity C. Accordingly, even when a multi-layered inorganic layer is deposited, it may be difficult to form a coating layer having a uniform thickness on all surfaces. Consequently, a coating layer may not be formed or an unnecessarily thin layer may be deposited, resulting in reliability failure in some areas.

Therefore, an area where it is difficult to form a uniform coating layer, for example, all or part of the area in a structure in which an inclination angle is great, may be covered with a silicon layer to compensate for this limitation.

A coating layer 361 may include three or more coating layers 361a, 361b, and 361c, and a coating layer 362 may include three or more coating layers 362a, 362b, and 362c. The coating layers 361 and 362 may each have a thickness of 40 nm or more, and may be formed to have the same configuration as the first and second coating layers 161 and 162 included in the light-emitting device package 100 of FIG. 2.

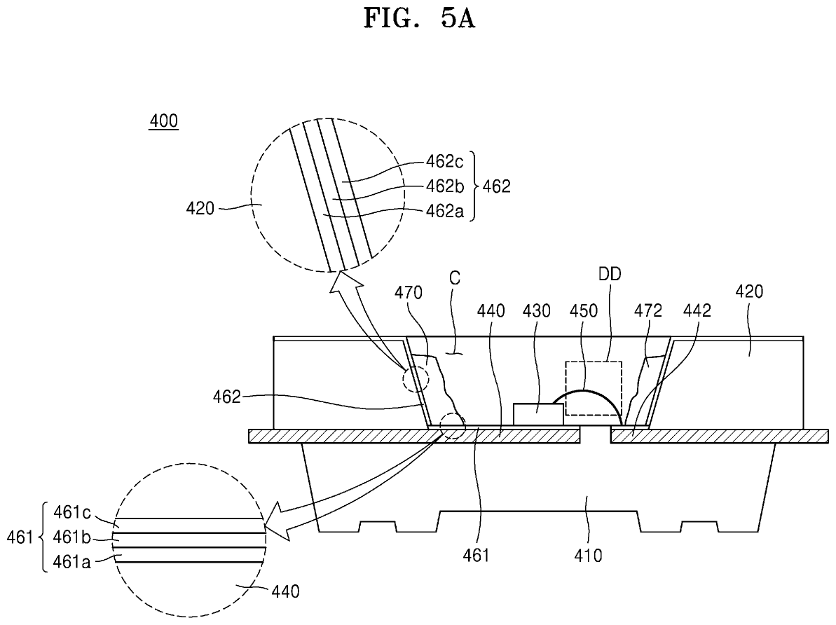

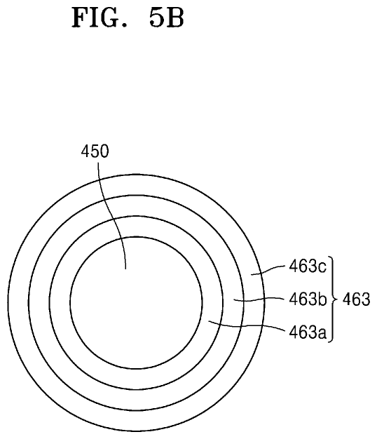

FIG. 5A is a cross-sectional view illustrating a light-emitting device package 400 according to another embodiment.

Referring to FIG. 5A, in the light-emitting device package 400 according to another embodiment, a coating layer may also be formed on a wire 450, compared to the embodiment of FIG. 4. In the light-emitting device package 300 of FIG. 4, reliability and reflectance are enhanced by forming the coating layer before a chip is bonded. In the light-emitting device package 400 of FIG. 5A, reliability and reflectance may be enhanced by coating wires and electrodes after wire bonding is performed.

FIG. 5B is an enlarged cross-sectional view of region DD of FIG. 5A. A third coating layer 463 may be formed on the wire 450.

Referring to FIGS. 5A and 5B, a first coating layer 461 may include three or more coating layers 461a, 461b, and 461c, a second coating layer 462 may include three or more coating layers 462a, 462b, and 462c, and the third coating layer 463 may include three or more coating layers 463a, 463b, and 463c.

The first to third coating layers 461, 462 and 463 may each have a thickness of 80 nm or less and may be formed to have the same configuration as the first to third coating layers 261, 262 and 263 included in the light-emitting device package 200 of FIGS. 3A and 3B.

The light-emitting device package according to the inventive concept may be applied to any light-emitting device products using a lead frame package.

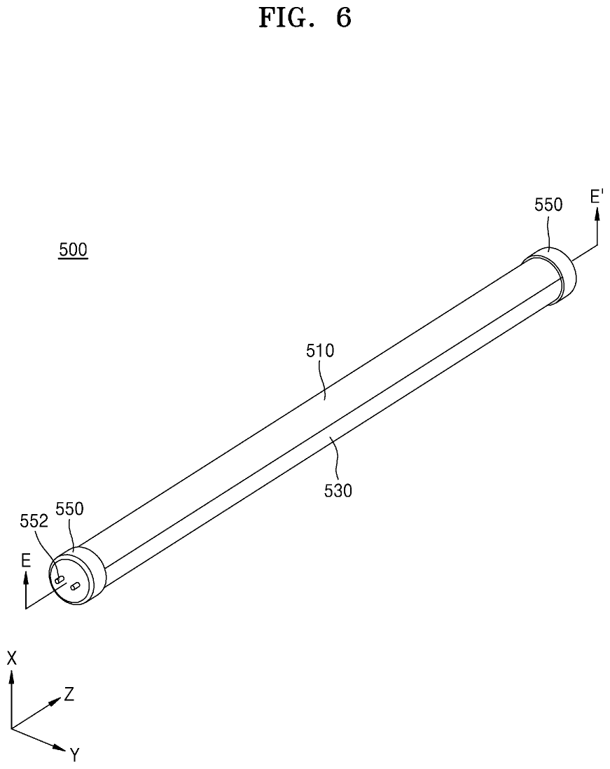

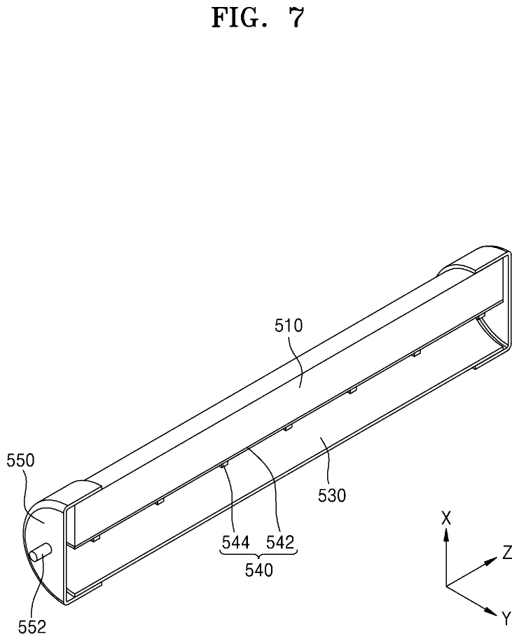

FIG. 6 is a perspective view illustrating a lighting device 500 including a light-emitting device package, according to an embodiment, and FIG. 7 is a cross-sectional view of the lighting device 500 of FIG. 6 taken along line E-E′ of FIG. 6.

Referring to FIGS. 6 and 7, the lighting device 500 may include a body 510, a cover 530 coupled to the body 510, and end caps 550 respectively at opposite ends of the body 510.

A light-emitting device module 540 may be coupled to the lower surface of the body 510, and the body 510 may be formed of a metal material having excellent conductivity and heat dissipation effects so that heat generated in light-emitting device packages 544 is dissipated to the outside through the upper surface of the body 510.

The light-emitting device packages 544 may be mounted in multiple columns and in multiple rows on a PCB 542 to form an array and may be mounted at equal intervals, or may be mounted with various separation distances to adjust brightness or the like. A metal core PCB (MCPCB) or an FR4 PCB may be used as the PCB 542.

Because the light-emitting device package 544 includes a coating layer (not shown) having a multi-layered structure, the light-emitting device package 544 may have improved sulfur resistance, moisture resistance, and flame resistance. Accordingly, reliability and efficiency of the light-emitting device package 544 may be improved, and reliability and performance of the light-emitting device package 544 and the lighting device 500 including the light-emitting device package 544 may be improved.

Because the lighting device 500 illustrated in FIGS. 6 and 7 has high reliability, the lighting device 500 may be particularly effective when used in outdoor lights with various environmental changes, for example, garden lights, security lights, street lights, or the like.

The light-emitting device package 544 may correspond to any one of the light-emitting device packages 100, 200, 300, and 400 described with reference to FIGS. 1 to 5B.

The cover 530 may be formed to have a circular shape to surround the lower surface of the body 510, but the inventive concept is not limited thereto.

The cover 530 may protect the light-emitting device module 540 from external foreign materials. The cover 530 may include diffusion particles in order to prevent glare of light generated from the light-emitting device package 544 and allow light to be uniformly emitted to the outside. A prism pattern or the like may be formed in at least one of the inner and outer surfaces of the cover 530. In addition, a fluorescent material such as a phosphor may be applied onto at least one of the inner and outer surfaces of the cover 530.

Because light generated from the light-emitting device package 544 is emitted to the outside through the cover 530, the cover 530 may have excellent light transmittance and may have sufficient heat resistance to withstand heat generated by the light-emitting device package 544. Accordingly, the cover 530 may be formed of a material including polyethylene terephthalate (PET), polycarbonate (PC), or polymethyl methacrylate (PMMA).

The end caps 550 may be respectively located at opposite ends of the body 510 and may seal a power supply (not shown). Because a power pin 552 is formed in the end cap 550 with a form factor of the existing fluorescent lamp and an arrangement thereof, the existing fluorescent lamp may be replaced with the lighting device 500 according to an embodiment without using a separate device for adaptation of the lighting device 500.

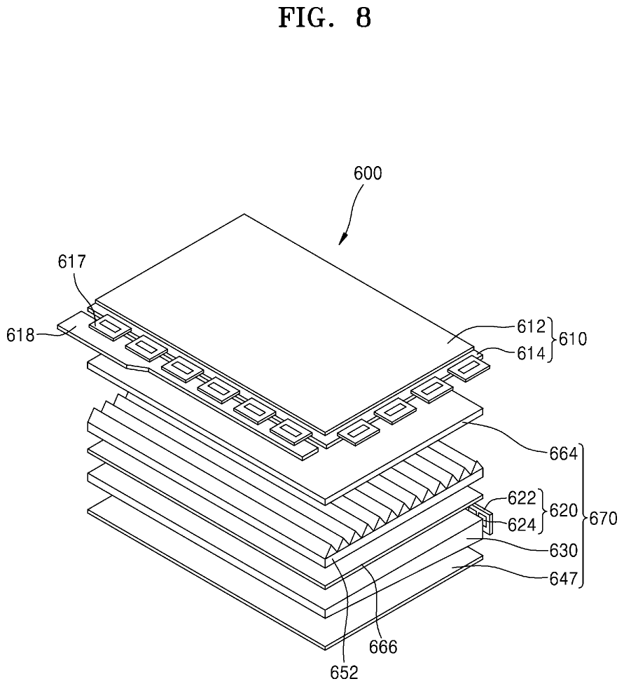

FIG. 8 is an exploded perspective view of a liquid crystal display 600 including a light-emitting device package, according to an embodiment.

FIG. 8 illustrates an edge-light type liquid crystal display 600. The edge-light type liquid crystal display 600 may include a liquid crystal display panel 610 and a backlight unit 670 that provides light to the liquid crystal display panel 610.

The liquid crystal display panel 610 may display an image by using light provided from the backlight unit 670. The liquid crystal display panel 610 may include a color filter substrate 612 and a thin-film transistor substrate 614, which face each other with liquid crystals therebetween.

The color filter substrate 612 may implement colors of an image displayed on the liquid crystal display panel 610.

The thin-film transistor substrate 614 may be electrically connected through a driving film 617 to a PCB 618 on which a plurality of circuit components are mounted. The thin-film transistor substrate 614 may apply, to liquid crystals, a driving voltage provided from the PCB 618 in response to a driving signal provided from the PCB 618.

The thin-film transistor substrate 614 may include a pixel electrode and a thin-film transistor formed as a thin-film on another substrate formed of a transparent material such as glass or plastic.

The backlight unit 670 may include a light-emitting device module 620 that outputs light, a light guide plate 630 that converts light provided from the light-emitting device module 620 into a form of a surface light source and provides the resulting light to the liquid crystal display panel 610, a plurality of films 652, 666, and 664 that uniformly distribute light provided from the light guide plate 630 and improve normal incidence, and a reflection sheet 647 that reflects light emitted from the rear of the light guide plate 630 to the light guide plate 630.

The light-emitting device module 620 may include a plurality of light-emitting device packages 624 and a PCB substrate 622 on which the light-emitting device packages 624 are mounted to form an array. In this case, reliability of mounting of the bent light-emitting device package 624 may be improved.

The backlight unit 670 may include a diffusion film 666 that diffuses light incident from the light guide plate 630 toward the liquid crystal display panel 610, a prism film 652 that condenses diffused light so as to improve normal incidence, and a protection film 664 that protects the prism film 652.

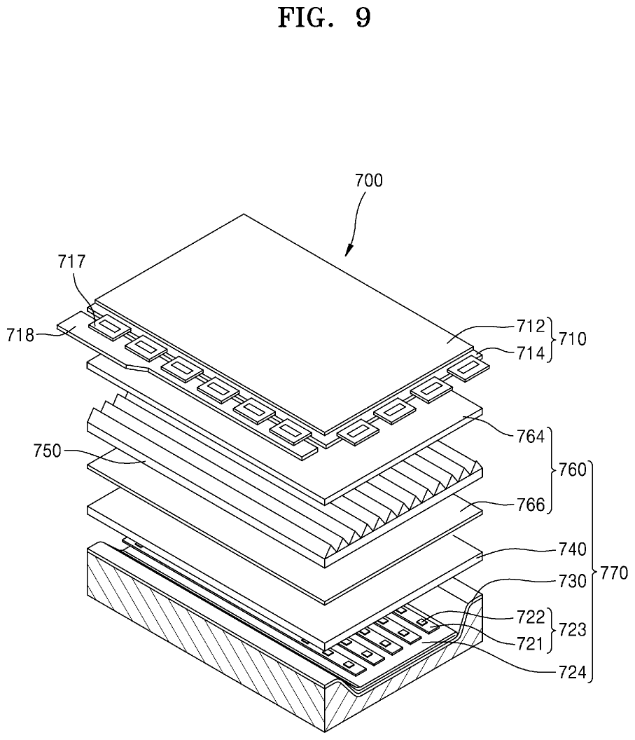

FIG. 9 is an exploded perspective view of a liquid crystal display including a light-emitting device package, according to an embodiment. However, the parts illustrated in and described with reference to FIG. 8 are not repeatedly described in detail.

FIG. 9 illustrates a direct-type liquid crystal display 700. The liquid crystal display 700 may include a liquid crystal display panel 710 and a backlight unit 770 that provides light to the liquid crystal display panel 710.

Because the direct-type liquid crystal display panel 710 is the same as described above with reference to FIG. 8, a detailed description thereof is omitted.

The backlight unit 770 may include a plurality of light-emitting device modules 723, a reflection sheet 724, a lower chassis 730 in which the light-emitting module 723 and the reflection sheet 724 are accommodated, a diffusion plate 740 disposed above the light-emitting device module 723, and a plurality of optical films 760.

The light-emitting device module 723 may include a plurality of light-emitting device packages 722 and a PCB substrate 721 on which the light-emitting device packages 722 are mounted to form an array.

The reflection sheet 724 may improve light use efficiency by reflecting light generated by the light-emitting device package 722 in a direction where the liquid crystal display panel 710 is located.

Light generated by the light-emitting device module 723 may be incident on the diffusion plate 740, and an optical film 760 may be disposed on the diffusion plate 740. The optical film 760 may include a diffusion film 766, a prism film 750, and a protection film 764.

While the inventive concept has been particularly shown and described with reference to embodiments thereof, it will be understood that various changes in form and details may be made therein without departing from the spirit and scope of the following claims.

What is claimed is:

1. A light-emitting device package comprising:
a mold;
a first electrode and a second electrode that are at least partially buried in the mold;
a first light source disposed on the first electrode and electrically connected thereto; and
a coating layer disposed on a first portion of the first electrode and a second portion of the second electrode,
wherein a thickness of the coating layer is 40 nm or more.

2. The light-emitting device package of claim 1,
wherein the mold is provided with a recess that exposes the first portion of the first electrode and the second portion of the second electrode,
wherein the first light source is disposed in the recess, and
wherein the coating layer comprises at least three layers.

3. The light-emitting device package of claim 2,
wherein each of the at least three layers includes at least one of Al₂O₃, TiO₂, SiO₂, CrO, and Ti.

4. The light-emitting device package of claim 2,
wherein the at least three layers include an Al₂O₃ layer having a thickness of about 20 nm, a TiO₂ layer having a thickness of about 20 nm, and a SiO₂ layer having a thickness of about 15 nm that are sequentially stacked.

5. The light-emitting device package of claim 2,
wherein the at least three layers include an Al₂O₃ layer having a thickness of about 15 nm, a TiO₂ layer having a thickness of about 30 nm, and a SiO₂ layer having a thickness of about 10 nm that are sequentially stacked.

6. The light-emitting device package of claim 2,
wherein the at least three layers include an Al₂O₃ layer having a thickness of about 20 nm, a SiO₂ layer having a thickness of about 10 nm, and a TiO₂ layer having a thickness of about 30 nm that are sequentially stacked.

7. The light-emitting device package of claim 1,
wherein each of the first electrode and the second electrode includes copper (Cu), and
wherein an upper surface of each of the first portion of the first electrode and the second portion of the second electrode is plated with silver (Ag), and
wherein the first light source is disposed on the upper surface of the first portion of the first electrode.

8. The light-emitting device package of claim 1,
wherein the first light source is wire-bonded to the second electrode.

9. The light-emitting device package of claim 1,
wherein the first light source includes two or more light-emitting diodes connected to the first and second electrodes in parallel.

10. The light-emitting device package of claim 2, further comprising:
a silicon layer covering a portion of an inner surface of the recess.

11. A light-emitting device package comprising:
a mold provided with a recess;
a first electrode and a second electrode that are at least partially buried in the mold;
a first light source disposed in the recess and electrically connected to the first electrode;
a silver (Ag) wire connecting the first light source to the second electrode; and
a coating layer disposed on a first portion of the first electrode, a second portion of the second electrode, an outer surface of the Ag wire, and an inner surface of the recess,
wherein a thickness of the coating layer is 80 nm or less.

12. The light-emitting device package of claim 11,
wherein the coating layer comprises at least three layers, and
wherein each of the at least three layers includes at least one of Al₂O₃, TiO₂, SiO₂, CrO, and Ti.

13. The light-emitting device package of claim 12,
wherein the at least three layers include an Al₂O₃ layer having a thickness of about 20 nm, a TiO₂ layer having a thickness of about 20 nm, and a SiO₂ layer having a thickness of about 20 nm that are sequentially stacked.

14. The light-emitting device package of claim 12,
wherein the at least three layers include an Al₂O₃ layer having a thickness of about 15 nm, a TiO₂ layer having a thickness of about 30 nm, and a SiO₂ layer having a thickness of about 10 nm that are sequentially stacked.

15. The light-emitting device package of claim 12,
wherein the at least three layers include an Al₂O₃ layer having a thickness of about 20 nm, a SiO₂ layer having a thickness of about 10 nm, and a TiO₂ layer having a thickness of about 30 nm that are sequentially stacked.

16. The light-emitting device package of claim 11,
wherein each of the first electrode and the second electrode includes copper (Cu), and
wherein an upper surface of each of the first portion of the first electrode and the second portion of the second electrode is plated with Ag.

17. The light-emitting device package of claim 11,
wherein the first light source includes two or more light-emitting diodes connected to the first and second electrodes in parallel.

18. The light-emitting device package of claim 11, further comprising:
a silicon layer covering a portion of an inner surface of the recess.

19. A lighting device comprising a light-emitting device package,
wherein the light-emitting device package comprises:
a mold provided with a plurality of electrodes and a recess partially exposing a first electrode and a second electrode among the plurality of electrodes;
a light source electrically connected to the first electrode;
a coating layer disposed on a first portion of the first electrode and a second portion of the second electrode, and
wherein a thickness of the coating layer is selected from a range of 40 nm to 80 nm.

20. The lighting device of claim 19, further comprising:
a silver (Ag) wire connecting the light source to the second electrode, wherein the coating layer is further disposed on the Ag wire.
